(19) United States
(12) Patent Application Publication
(10) Pub. No.: US 2014/0151332 A1
(43) Pub. Date: Jun. 5, 2014

(54) SUBSTRATE SUPPORTING UNIT AND SUBSTRATE TREATING APPARATUS AND METHOD

(71) Applicant: Takayuki FUKASAWA, Seoul (KR)

(72) Inventor: Takayuki FUKASAWA, Seoul (KR)

(21) Appl. No.: 13/933,002

(22) Filed: Jul. 1, 2013

(30) Foreign Application Priority Data
Nov. 30, 2012 (KR) 10-2012-0138064

(51) Int. Cl. H01J 37/32; H01L 21/687

(52) U.S. Cl. CPC H01J 37/32009; H01L 21/68785
USPC 216/67; 156/345.51; 156/345.37

(57) ABSTRACT

An apparatus for treating a substrate may include a process chamber. The process chamber may include a reaction space and an opening portion for receiving the substrate into the reaction space. The apparatus may further include a dielectric layer. The apparatus may further include a plurality of support elements disposed on the dielectric layer and configured to contact a bottom surface of the substrate for supporting the substrate. The plurality of support elements may include a first support element and a second support element immediately neighboring the first support element.

### CROSS-REFERENCE TO RELATED APPLICATION

This U.S. non-provisional patent application claims priority under 35 U.S.C. §119 to and benefit of Korean Patent Application No. 10-2012-0138064, filed on Nov. 30, 2012, the contents of which are incorporated hereby by reference.

### BACKGROUND

1. Field of the Invention

The present invention is related to a substrate supporting unit and a substrate treating apparatus (or substrate processing apparatus) having the substrate supporting unit. The substrate supporting unit may support a substrate (e.g., a transistor substrate) when one or more treatment processes are performed on the substrate in the substrate treating apparatus.

2. Description of the Related Art

A substrate treating apparatus may be used in treating a substrate for manufacturing an electronic device, such as a flat-panel display device and/or a semiconductor device. In general, the substrate treating apparatus includes a process chamber and a substrate supporting unit disposed inside the process chamber to support the substrate. The substrate treating apparatus may perform a predetermined process on the substrate using a process gas supplied into the process chamber.

To prevent the substrate from being overheated by an atmosphere inside the process chamber when the predetermined process is performed on the substrate, a cooling unit is disposed under the substrate supporting unit to cool the substrate. The substrate supporting unit, which is disposed between the substrate and the cooling unit, may transfer heat from the substrate to the cooling system, and the cooling system may dissipate the heat. In general, the substrate supporting unit may include different materials that transfer heat at substantially different rates. The substantially different heat transfer rates of the substrate supporting unit may cause different portions of the substrate to have substantially different temperatures during the process.

The temperature differences of different portions of the substrate may exert negative influence on the quality of the process performed on the substrate. For example, the accuracy of an etch process or a deposition process may be unsatisfactory.

### SUMMARY

One or more embodiments of the invention may be related to an apparatus for treating a substrate. The apparatus may include a process chamber. The process chamber may include a processing space and an opening portion for receiving the substrate into the processing space. The apparatus may further include a dielectric layer. The apparatus may further include a plurality of support elements disposed on the dielectric layer and configured to contact a bottom surface of the substrate for supporting the substrate. The plurality of support elements may include a first support element and a second support element immediately neighboring the first support element. A distance between the first support element and the second support element may be less than or equal to two times a thickness of the substrate. The configuration of the plurality of support elements may ensure that the temperature distribution on the upper surface, i.e., the processed surface, of the substrate is sufficiently uniform when the substrate is processed. Advantageously, the substrate process quality may be satisfactory.

In one or more embodiments, the distance is greater than or equal to 0.01 mm.

In one or more embodiments, the distance is a maximum distance between the first support element and the second support element in a direction parallel to a bottom surface of the dielectric layer.

In one or more embodiments, the height of the opening portion is in a direction perpendicular to a bottom surface of the dielectric layer.

In one or more embodiments, the apparatus may include a cooling member, wherein the dielectric layer is disposed between the cooling member and the plurality of support elements.

In one or more embodiments, the first support element has a polygonal top surface configured to contact the bottom surface of the substrate.

In one or more embodiments, the support elements are disposed in rows in a first direction and are disposed in a zigzag form with respect to a second direction that is perpendicular to the first direction.

In one or more embodiments, the apparatus may include a first protrusion disposed on the dielectric layer and disposed between the first support element and the second support element, wherein the first protrusion is shorter than the first support element in a direction perpendicular to a bottom surface of the dielectric layer.

In one or more embodiments, the apparatus may include a second protrusion disposed on the dielectric layer and disposed between the first support element and the second support element, wherein the second protrusion is shorter than the first support element in the direction perpendicular to a bottom surface of the dielectric layer.

In one or more embodiments, the apparatus may include an electrostatic chuck, wherein the dielectric layer is disposed between the electrostatic chuck and the first protrusion.

One or more embodiments of the invention may be related to a device for supporting a substrate inside a process chamber. The process chamber may include a processing space and an opening portion for receiving the substrate into the processing space. The device may include a dielectric layer. The device may further include a plurality of support elements disposed on the dielectric layer and configured to contact a bottom surface of the substrate for supporting the substrate. The plurality of support elements may include a first support element and a second support element immediately neighboring the first support element. In one or more embodiments, the device may include a protrusion disposed on the dielectric layer and disposed between the first support element and the second support element, wherein the protrusion is shorter than the first support element in a direction perpendicular to a bottom surface of the dielectric layer.

In one or more embodiments, the device may include a protrusion disposed on the dielectric layer and disposed between the first support element and the second support element, wherein the protrusion is narrower than the first support element in a direction parallel to a bottom surface of the dielectric layer.

One or more embodiments of the invention may be related to a method for treating a substrate. The method may include the following steps: disposing the substrate inside a process chamber; using a plurality of support elements to contact a bottom surface of the substrate for supporting the substrate, wherein the plurality of support elements includes a first support element and a second support element immediately neighboring the first support element, wherein a distance between the first support element and the second support element is less than or equal to two times a thickness of the substrate; processing the substrate inside the process chamber; and cooling the substrate using a cooling member, wherein a first heat is transferred from the substrate through the plurality of support members to the cooling member.

In one or more embodiments, the distance is greater than or equal to 0.01 mm.

In one or more embodiments, the method may include using an electrostatic chuck to secure the substrate on the plurality of support elements. A total contact area of the bottom surface of the substrate contacted by the plurality of support elements may have a first area size. An area of the dielectric layer contacted by the electrostatic chuck may have a second area size. A ratio of the first area size to the second area size may be less than or equal to 80%.

In one or more embodiments, the ratio of the first area size to the second area size is greater than or equal to 0.1%.

In one or more embodiments, the ratio of the first area size to the second area size is less than or equal to 50% and is greater than or equal to 0.1%.

In one or more embodiments, the first support element and the second support element are disposed on a dielectric layer, a protrusion is disposed on the dielectric layer and disposed between the first support element and the second support element, the protrusion is shorter than the first support element in a direction perpendicular to a bottom surface of the dielectric layer, and a second heat is transferred from the substrate through a gas to the protrusion. In one or more embodiments, the second heat is transferred through the protrusion to the cooling element.

One or more embodiments of the present invention may be related to a substrate supporting unit capable of maximizing uniformly of temperature of a substrate while processes are performed on the substrate.

One or more embodiments of the present invention may be related to a substrate treating apparatus having the substrate supporting unit to optimally perform a process on the substrate.

One or more embodiments of the invention may be related to a substrate supporting unit for use in a substrate treating apparatus. The substrate supporting unit may include a first dielectric layer configured to be disposed under the substrate and a plurality of protrusions that includes a dielectric material and is disposed on the first dielectric layer to contact and support the substrate. The protrusions are spaced from each other and a distance between two immediately adjacent protrusions among the protrusions is in a range of about 0.01 mm to about two times of a thickness of the substrate.

One or more embodiments of the invention may be related to an apparatus for treating a substrate. The apparatus may include a process chamber that includes a reaction space in which the substrate is treated and the aforementioned substrate supporting unit disposed inside the process chamber to support the substrate.

According to the above, the distance between the protrusions that support the substrate may be optimized. Accordingly, temperature differences between different areas of the substrate may be minimized. Advantageously, the quality (and/or results) of processes performed on the substrate, e.g., etching processes and/or deposition processes, may be satisfactory.

### BRIEF DESCRIPTION OF THE DRAWINGS

The above and other advantages of the present invention will become readily apparent by reference to the following detailed description when considered in conjunction with the accompanying drawings wherein:

FIG. 1 is a schematic representation illustrating a substrate treating apparatus according to one or more embodiments of the present invention;

FIG. 2 is an enlarged view illustrating a substrate supporting unit illustrated in FIG. 1;

FIG. 3 is a plan view of a substrate supporting unit illustrating a first dielectric layer and a plurality of protrusions according to one or more embodiments of the present invention;

FIGS. 4A to 4D are plan views of substrate supporting units illustrating protrusions according to one or more embodiments of the present invention;

FIG. 5 is an enlarged view illustrating a substrate supporting unit according to one or more embodiments of the present invention;

FIGS. 6A and 6B are views illustrating a method of manufacturing the first dielectric layer and the protrusions illustrated in FIG. 1 according to one or more embodiments of the present invention; and

FIGS. 7A to 7C are views illustrating a method of manufacturing the first dielectric layer and the protrusions illustrated in FIG. 4B according to one or more embodiments of the present invention.

### DETAILED DESCRIPTION

In this specification, if an element or layer is referred to as being “on”, “connected to”, or “coupled to” another element or layer, it can be directly on, directly connected, or directly coupled to the other element or layer, or intervening elements or layers may be present. In contrast, if an element is referred to as being “directly on”, “directly connected to”, or “directly coupled to” another element or layer, there are no (intended) intervening elements or layers (except possible environmental elements, such as air) present. Like numbers may refer to like elements in the specification. As used herein, the term “and/or” may include any and all combinations of one or more of the associated listed items.

Although the terms first, second, etc. may be used herein to describe various elements, components, regions, layers and/or sections, these elements, components, regions, layers and/or sections should not be limited by these terms. These terms may be used to distinguish one element, component, region, layer or section from another region, layer or section. Thus, a first element, component, region, layer or section discussed below could be termed a second element, component, region, layer or section without departing from the teachings of the present invention. The description of an element as a “first” element may not require or imply the presence of a second element or other elements. The terms first, second, etc. may also be used herein to differentiate different categories of elements. For conciseness, the terms first, second, etc. may represent first-type (or first-category), second-type (or second-category), etc., respectively.

Spatially relative terms, such as “beneath”, “below”, “lower”, “above”, “upper”, etc., may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments and is not intended to be limiting of the invention. As used herein, the singular forms, “a”, “an”, and “the” may include the plural forms as well, unless the context clearly indicates otherwise. The terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

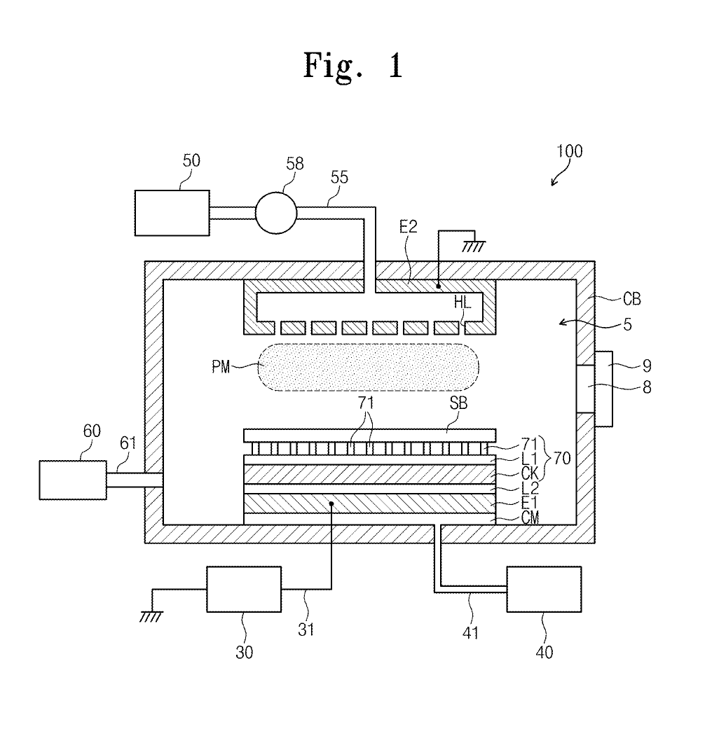

FIG. 1 is a schematic representation illustrating a substrate treating apparatus 100 (or substrate processing apparatus 100) according to one or more embodiments of the present invention.

Referring to FIG. 1, the substrate treating apparatus 100 may treat (or process) the substrate SB using plasma PM. In one or more embodiments, the substrate treating apparatus 100 may perform an etch process on a thin layer (not shown) formed on the substrate SB, and the substrate SB may be a glass substrate. In one or more embodiments, the substrate SB may be a plastic substrate, and the substrate treating apparatus 100 may perform a deposition process on the substrate SB using at least one of a chemical vapor deposition method and a sputtering method.

The substrate treating apparatus 100 includes a process chamber CB, a first electrode E1, a second electrode E2, a source voltage generator 30, a cooling member CM, a coolant supply unit 40, a gas supply unit 50, a gas ventilation part 60, and a substrate supporting unit 70.

The process chamber CB may include a reaction space 5 in which an etch process may be performed on the substrate SB. The process chamber CB may have an opening portion 8 formed through a sidewall of the process chamber CB. The process chamber CB may include a shutter 9 disposed at the opening portion 8 for opening and closing the opening portion 8. The substrate SB may enter the process chamber CB through the opening portion 8 and may exit the process chamber CB through the opening portion 8.

The first electrode E1 may be disposed under the substrate SB in the process chamber CB. The second electrode E2 may be disposed at an upper portion of the reaction space 5 in the process chamber CB. The first electrode E1 is electrically connected to the source voltage generator 30 through a source voltage supply line 31. An electric field may be formed between the first electrode E1 and the second electrode E2 by a high frequency source voltage generated by the source voltage generator 30 and applied to the first electrode E1. The process gas supplied into the reaction space 5 may be excited by the electric field to generate the plasma PM for performing the etch process on the substrate SB.

The cooling member CM may contact the first electrode E1 to cool the first electrode E1. The coolant supply unit 40 may supply a coolant, such as a cooling gas, to the cooling member CM through a coolant pipe 41. Heat of the substrate SB heat generated in the reaction space 5 may be transferred to the first electrode E1, the first electrode E1 may be cooled by the cooling member CM, and thus the substrate SB may be prevented from being overheated.

In one or more embodiments, a path is formed inside the cooling member to be connected to the coolant pipe 41, the coolant flows through the path and the coolant pipe 41, and the cooling member CM is disposed under the first electrode E1. In one or more embodiments, a path through which the coolant flows may be formed inside the first electrode E1 and may be connected to the coolant pipe 41.

The gas supply unit 50 may supply the process gas, which may be used to generate the plasma PM, to the process chamber CB. In one or more embodiments, the process gas includes a helium gas. In one or more embodiments, the process gas may include one or more of an oxygen gas, a nitride gas, a fluoride gas, a hydrogen gas, an argon gas, etc. A gas supply line 55 is connected between the gas supply unit 50 and the process chamber CB, and a flowmeter 58 is coupled with the gas supply line 55 to control a flow amount of the process gas flowing through the gas supply line 55.

In one or more embodiments, the second electrode E2 may be connected to the gas supply line 55 to receive the process gas. The second electrode E2 may include a plurality of holes HL, and the process gas may be substantially uniformly supplied to the reaction space 5 through the holes HL.

The gas ventilation unit 60 is connected to the process chamber CB through a ventilation pipe 61. In one or more embodiments, the gas ventilation unit 60 may include a vacuum pump (not shown), and a pressure of the reaction space 5 may be controlled by the vacuum pump.

The substrate supporting unit 70 is disposed inside the process chamber 100 to support the substrate SB. In one or more embodiments, the substrate supporting unit 70 includes a chuck CK, a first dielectric layer L1, and a plurality of protrusions 71.

The chuck CK is disposed on the first electrode E1 with a second dielectric layer L2 being disposed between the chuck CK and the first electrode E1. In one or more embodiments, the chuck CK may be an electrostatic chuck that includes a metal electrode. In one or more embodiments, the chuck CK may generate an electrostatic force using the metal electrode and may secure the substrate SB in a horizontal orientation using the electrostatic force.

The first dielectric layer L1 covers the chuck CK. The first dielectric layer L1 includes a dielectric material. In one or more embodiments, the dielectric material may include aluminum oxide (Al₂O₃). In one or more embodiments, the dielectric material may include one or more of silicon oxide (SiO₂), zirconium oxide (ZrO₃), silicon nitride SiN₄, etc.

The protrusions 71 are disposed on the first dielectric layer L1 and may contact a rear surface of the substrate SB. The protrusions 71 may be formed of the same material as the first dielectric layer L1. In one or more embodiments, the first dielectric layer L1 and the protrusions 71 may be integrally formed.

The protrusions 71 are spaced apart from each other and disposed on the first dielectric layer L1. In one or more embodiments, a distance between two immediately neighboring protrusions (and/or every two immediately neighboring protrusions) of the protrusions 71 may be greater than or equal to 0.01 and may be smaller than or equal to two times of a thickness of the substrate SB. In one or more embodiments, the thickness of the substrate SB is about 0.9 mm, and the distance between two immediately neighboring protrusions of the protrusions 71 may be smaller than or equal to 1.8 mm.

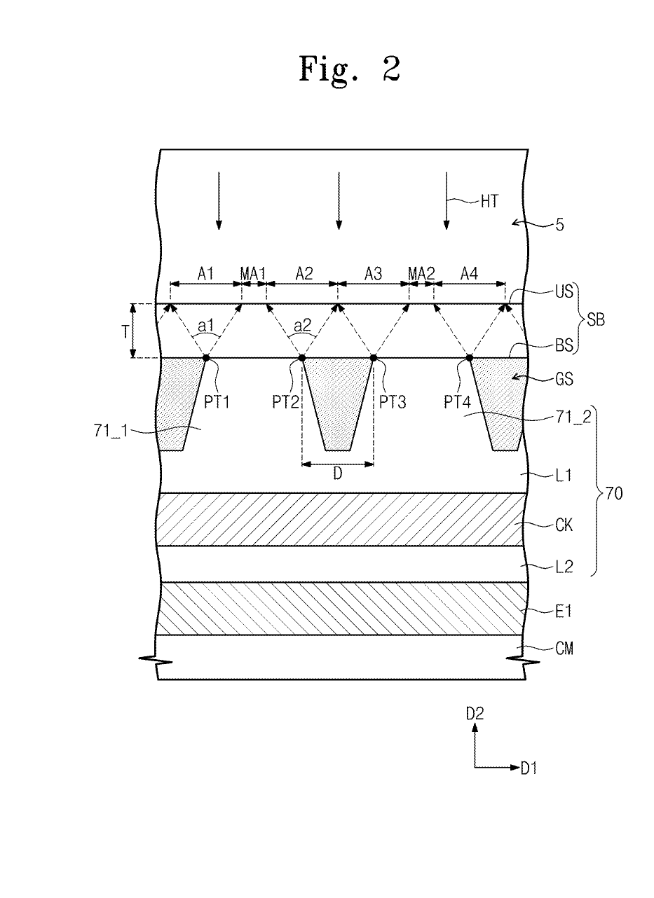

FIG. 2 is an enlarged view illustrating a substrate supporting unit illustrated in FIG. 1. FIG. 2 illustrates two immediately neighboring protrusions among the protrusions 71 of the substrate supporting unit 70, and the two protrusions will be referred to as a first protrusion 71_1 and a second protrusion 71_2. In one or more embodiments, each of the protrusions may have a trapezoid-shaped cross section along a plane that is perpendicular to the bottom surface BS of the substrate SB.

Referring to FIG. 2, the substrate SB is exposed in the reaction space 5 (into which the plasma PM is generated), and the substrate supporting unit 70 supports the substrate SB. When the etch process is performed on the thin layer formed on the substrate SB while the substrate SB is supported by the substrate supporting unit 70, the heat HT generated in the reaction space 5 may be sequentially transferred through the substrate SB, the substrate supporting unit 70, and the first electrode El to the cooling member CM. The cooling member CM may dissipate the heat through, for example, the coolant pipe 41 (illustrated in FIG. 1). In one or more embodiments, the first electrode E1, the substrate supporting unit 70, and the substrate SB are sequentially cooled by the cooling member CM.

When the substrate SB is being processed, a space between the substrate SB and the first dielectric layer L1 may be filled with the process gas GS, which has been provided from the gas supply unit 50 to generate the plasma PM. In one or more embodiments, the protrusions 71_1 and 71_2 include aluminum oxide, the process gas GS includes a helium gas, each of the protrusions 71_1 and 71_2 has a heat conductivity (or thermal conductivity) of about 26 Watt/meter·Kalvine and the process gas GS has a heat conductivity of about 0.16 Watt/meter·Kalvine. Therefore, the heat conductivity of each of the protrusions 71_1 and 71_2 is more than one hundred times that of the process gas GS.

Thus, when cooling is performed by the cooling member CM, a temperature of each of the protrusions 71_1 and 71_2 may be lower than a temperature of the process gas GS because of the difference between the heat conductivity of each of the protrusions 71_1 and 71_2 and the heat conductivity of the process gas GS. Therefore, portions of the bottom surface BS of the substrate SB that contact the protrusions 71_1 and 71_2 may be cooler than portions of the bottom surface BS that are exposed to the process gas GS. As a result, there may be different temperatures in the substrate SB.

In one or more embodiments, a structure of the substrate supporting unit 70 may minimize the temperature difference at the upper surface US of the substrate SB, where a substantially uniform temperature is desired.

A first contact point PT1 of the first protrusion 71_1 at the bottom surface BS of the substrate SB is exposed to the process gas GS. When the substrate SB is being processed in the substrate treatment apparatus 100, given the cooling performed by the cooling member CM and given the heat conductivity difference between the first protrusion 71_1 and the process gas GS, the temperature of the process gas GS is higher than the temperature of the protrusion 71_1; therefore, a first heat is transmitted to the first contact point PT1 from the process gas GS. The first heat is transmitted from the bottom surface BS of the substrate SB through the body of the substrate SB to The upper surface US of the substrate SB. In one or more embodiments, the substrate is a glass substrate and has an amorphous property; therefore, the first heat transmitted through the body of the substrate SB may spread within a first angle range a1. The first angle a1 may be about ±45 degrees with reference to a second direction D2 that is a normal line direction with respect to the substrate SB (i.e., the second direction is perpendicular to the bottom surface BS of the substrate SB), and thus the first angle a1 may be about 90 degrees.

The first heat may reach a first area A1 of the upper surface US and may not reach a first intermediate area MA1 of the upper surface US. As a result, the first surface A1 may have a first temperature, and the first intermediate area MA1 may have a second temperature, wherein the first temperature may be higher than the second temperature.

Analogous to the first contact point PT1, a second contact point PT2 of the first protrusion 71_1 that contacts the bottom surface BS of the substrate SB is exposed to the process gas GS.

When the substrate SB is processed in the substrate treatment apparatus 100, a second heat may be transmitted from the process gas GS through the second contact point PT2 through the body of the substrate SB to the upper surface US of the substrate SB. In the body of the substrate SB, the second heat may spread within a second angle range a2 that is equal to the first angle range a1. The second heat may reach a second area A2 of the upper surface US, such that the second area A2 also may have the first temperature.

Analogous to the areas A1 and A2 corresponding to contact points PT1 and PT2 of the first protrusion 71_1, a third area A3 of the upper surface US corresponding to a third contact point PT3 of the second protrusion 71_2 also may have the first temperature, and a fourth area A4 corresponding to a fourth contact point PT4 of the second protrusion 71_2 also may have the first temperature. A second intermediate area MA2 the third area A3 and the fourth area A4 may have the second temperature. Heat transfer patterns corresponding to points between contact points PT2 and PT3 may be analogous to the heat transfer pattern corresponding to each of contact points PT2 and PT3.

The first area A1, the first intermediate area MA1, the second area A2, the third area A3, the second intermediate area MA2, and the fourth area A4 are successively arranged on the upper surface US. The second area A2 and the third area A3 may abut each other to provide a substantial uniform temperature distribution on the upper surface US of the substrate SB. Accordingly, although the heat conductivity of each of the protrusions 71_1 and 71_2 is different from the heat conductivity of the process gas GS, there may only two temperatures, i.e., the first temperature and the second temperature, over the entire area of the upper surface US. The second temperature is primarily influenced by the temperature of the protrusions 71_1 and 71_2, and the first temperature is influenced by the temperature of the process gas GS and the temperature of the protrusions 71_1 and 71_2. In one or more embodiments, the difference between the first temperature and the second temperature may be substantially small, and satisfactory quality of the etch process may be maintained.

In contrast, if the second area A2 and the third area A3 were substantially spaced from each other with a substantial gap area of the upper surface US formed between the areas A2 and A3, the gap area might have a third temperature that is substantially primarily influenced by the temperature of the process gas GS and is greater than each of the first temperature and the second temperature. The difference between the third temperature and the second temperature might be substantially large. As a result, the quality of the etch process may be unsatisfactory.

In one or more embodiments, to prevent or minimize the gap area between the areas A2 and A3 for maximizing the temperature uniformity in the upper surface US, a (maximum) distance D between the protrusions 71_1 and 71_2 may be limited. The distance D may be limited according to the following formula:

0.01 mm<D<2×T (T=thickness of substrate)

In one or more embodiments, the thickness T of the substrate SB is about 0.9 mm, and the distance D is greater than 0.01 mm and smaller than 1.8 mm. In one or more embodiments, the distance D is limited by the formula, and the third areas A2 and A3 may abut or overlap each other. Accordingly, temperature uniformity in the upper surface US may be maximized.

In one or more embodiments, a ratio of the area in which the protrusions 71 contact the substrate SB to the area in which the first dielectric layer L1 contacts the chuck CK is in a range of about 0.1% to about 80%. In one or more embodiments, the ratio may be in a range of about 0.1% to about 50%. If the ratio between the areas is smaller than 0.1%, the size of the protrusions 71 may be too small such that the supporting force provided to the substrate SB by the protrusions 71 may be insufficient, and the inter-protrusion distance D may be too large such that the temperature in the upper surface US of the substrate SB may not be sufficient uniform; as a result, the process quality may be unsatisfactory. If the ratio between the areas is greater than 80%, the area in which the protrusions 71 contact the substrate SB may be too large such that by-products generated in the etch process may substantially accumulate on the protrusions 71 and may reduce the flatness of the substrate SB; as a result, the process quality may be unsatisfactory.

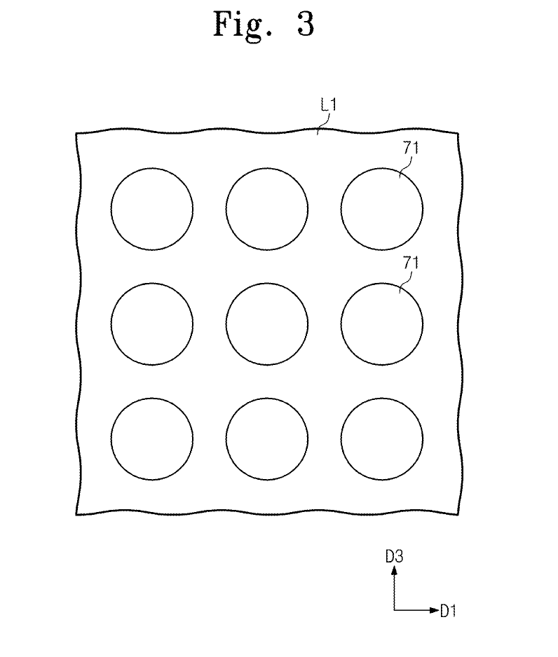

FIG. 3 is a plan view of the substrate supporting unit 70 illustrating a first dielectric layer and protrusions according to one or more embodiments of the present invention.

Referring to FIG. 3, the protrusions 71 are disposed on the first dielectric layer L1 and are spaced from each other. In one or more embodiments, each of the protrusions 71 has a circular shape when viewed in the plan view of the substrate support unit 70, and the protrusions 71 are arranged on the first dielectric layer L1 along a row direction D1 and a column direction D3 in a matrix form. In one or more embodiments, each of the protrusions 71 may have an oval shape when viewed in the plan view of the substrate support unit 70.

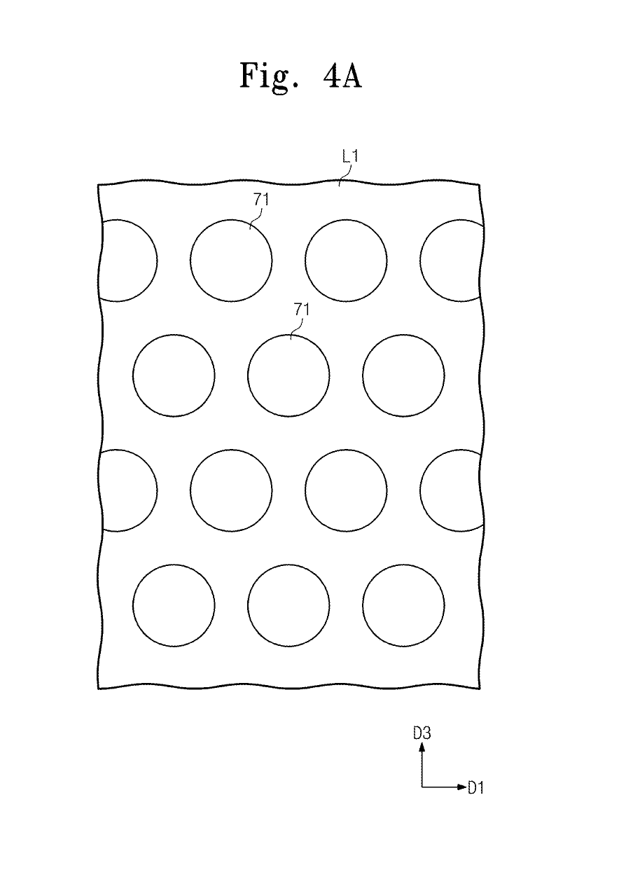

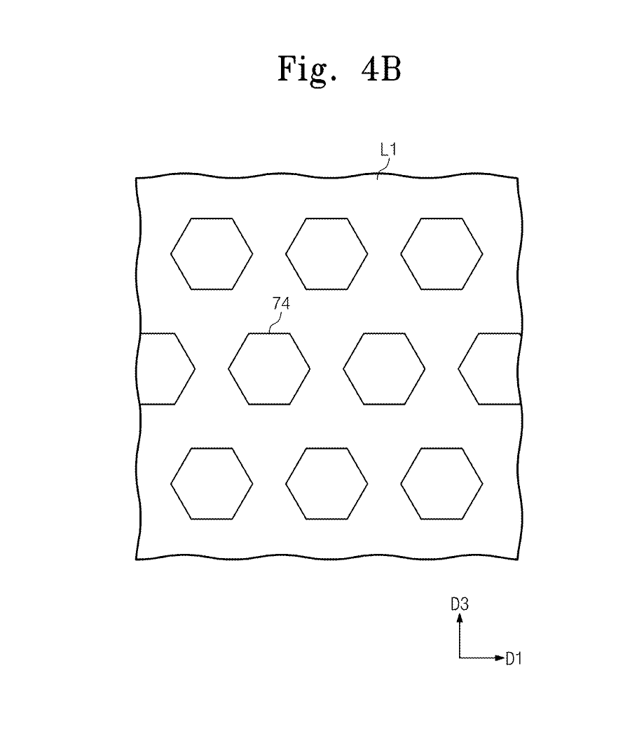

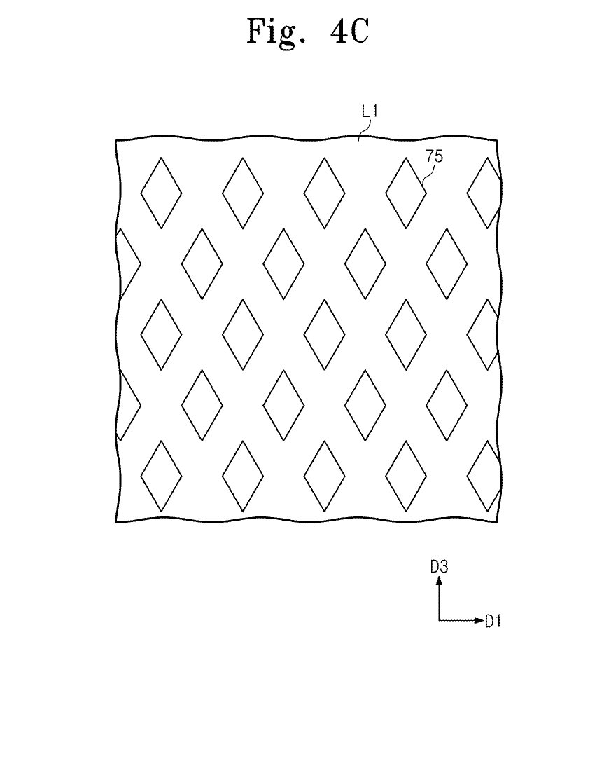

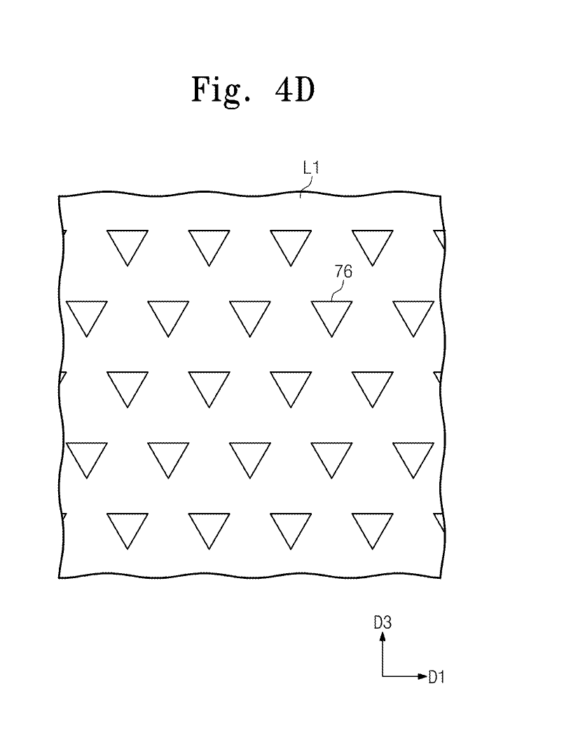

FIGS. 4A to 4D are plan views of substrate supporting units illustrating protrusions according to one or more embodiments of the present invention.

Referring to FIG. 4A, the protrusions 71 are disposed on the first dielectric layer L1 and are spaced from each other, and each of the protrusions 71 has a circular shape when viewed in a plan view of the associated substrate supporting unit. In one or more embodiments, the protrusions 71 are arranged along the row direction D1, and the rows of the protrusions 71 are offset and are arranged in a zigzag form with respect to the column direction D3. According to one or more embodiments, each of the protrusions 71 may have an oval shape when viewed in a plan view of the associated substrate supporting unit.

Referring to FIG. 4B, the protrusions 74 are disposed on the first dielectric layer L1 and are spaced apart from each other. In one or more embodiments, each of the protrusions 74 has a hexagonal shape when viewed in a plan view of the associated substrate supporting unit, the protrusions 74 are arranged along the row direction D1, and and the rows of the protrusions 74 are arranged in a zigzag form with respect to the column direction D3.

According to one or more embodiments, each of the protrusions 74 may have a polygonal shape, e.g., a pentagonal shape and/or an octagonal shape, and the protrusions 74 are arranged on the first dielectric layer L1 along the row direction D1 and the column direction D3 in a matrix form.

Referring to FIG. 4C, the protrusions 75 are disposed on the first dielectric layer L1 and are spaced from each other. In one or more embodiments, each of the protrusions 75 has a parallelogram shape when viewed in a plan view of the associated substrate supporting unit. In one or more embodiments, the protrusions 75 are arranged along the row direction D1, and the rows of the protrusions 75 are arranged in a zigzag form with respect to the column direction D3.

According to one or more embodiments, each of the protrusions 75 may have a quadrangular shape, e.g., a rectangular shape and/or a square shape, and the protrusions 75 are arranged on the first dielectric layer L1 along the row direction D1 and the column direction D3 in a matrix form.

Referring to FIG. 4D, the protrusions 76 are disposed on the first dielectric layer L1 and are spaced apart from each other. In one or more embodiments, each of the protrusions 76 has a triangular shape when viewed in a plan view of the associated substrate supporting unit. In one or more embodiments, the protrusions 76 are arranged along the row direction D1, and the rows of the protrusions 76 are arranged in a zigzag form with respect to the column direction D3.

According to one or more embodiments, each of the protrusions 76 may have a right-angled triangular shape, and the protrusions 76 are arranged on the first dielectric layer L1 along the row direction D1 and the column direction D3 in a matrix form.

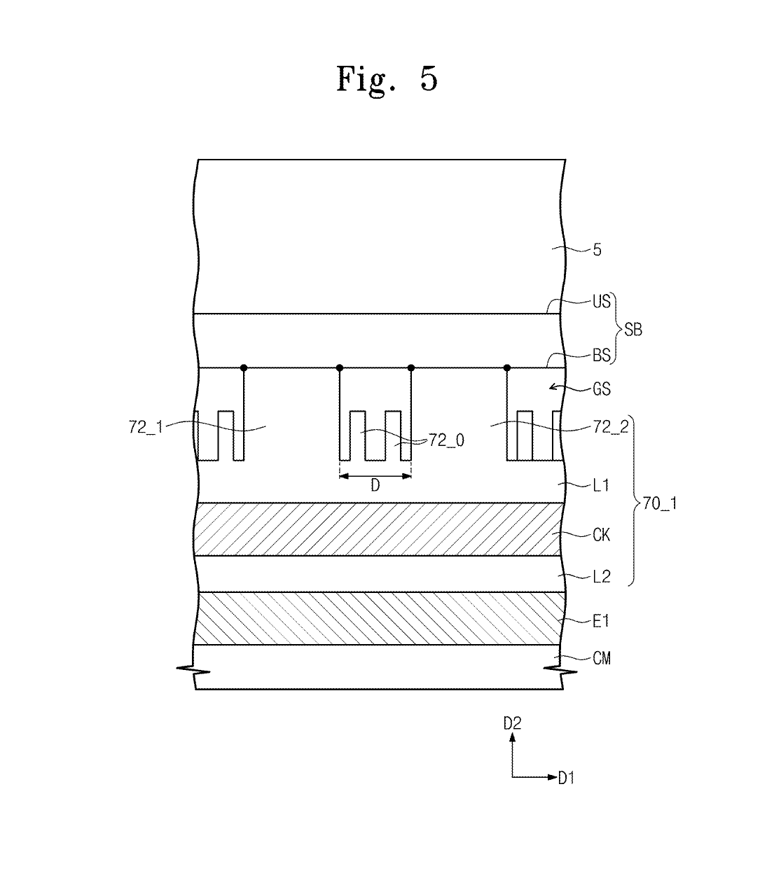

FIG. 5 is an enlarged view illustrating a substrate supporting unit according to one or more embodiments of the present invention. In FIG. 5, the same reference numerals may denote analogous elements discussed with reference to FIGS. 1 and 2. Detailed descriptions of the analogous elements may be omitted.

Referring to FIG. 5, a substrate supporting unit 70_1 includes a first dielectric layer L1 and a plurality of primary protrusions disposed on the first dielectric layer L1. Among the primary protrusions, a first protrusion 72_1 and a second protrusion 72_2, which are adjacent to each other, are illustrated in FIG. 5.

In one or more embodiments, each of the protrusions 72_1 and 72_2 has a rectangular and/or square cross section along a plane that is perpendicular to the lower surface BS (or bottom surface BS) of the substrate SB. Each of the protrusions 72_1 and 72_2 may (directly) contact the lower surface BS of the substrate SB.

In one or more embodiments, the substrate supporting unit 70_1 further includes a plurality of auxiliary protrusions 72_0 disposed on the first dielectric layer L1. The auxiliary protrusions 72_0 are disposed between adjacent primary protrusions. For instance, some of the auxiliary protrusions 72_0 are disposed between the first protrusion 72_1 and the second protrusion 72_2.

In one or more embodiments, each of the auxiliary protrusions 72_0 may have a height smaller than a height of each of the protrusions 72_1 and 72_2. Accordingly, the auxiliary protrusions 72_0 do not directly contact the substrate SB.

In one or more embodiments, portions of the substrate SB that overlap the auxiliary protrusions 72_0 (without overlapping primary protrusions) may be effectively cooled given the relative high heat conductivity of the auxiliary protrusions 72_0 in comparison with the heat conductivity of the process gas GS. Accordingly, a difference between the cooling effect of portions of the substrate SB that contact the primary protrusions and the cooling effect of portion of the substrate SB that do not contact the primary protrusions may be minimized. Advantageously, the substrate SB may be substantially uniformly cooled, and thus the substrate treatment quality may be satisfactory.

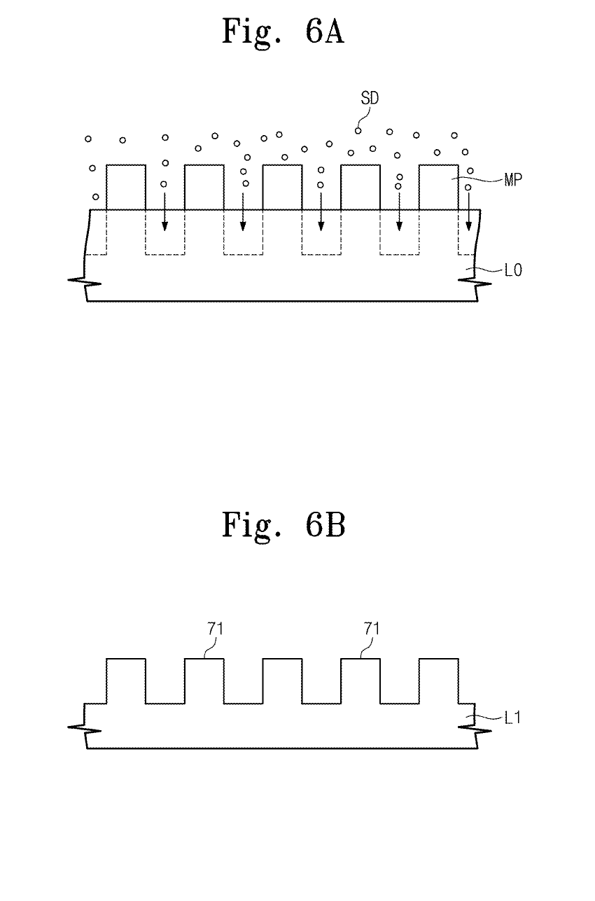

FIGS. 6A and 6B are views illustrating a method of manufacturing the first dielectric layer and the protrusions illustrated in FIG. 1 according to one or more embodiments of the present invention.

Referring to FIGS. 6A and 6B, a mask pattern MP is formed on a preliminary dielectric layer L0. Subsequently, portions of the preliminary dielectric layer L0 that are not covered by the mask pattern MP are etched using a sand blast method. In one or more embodiments, the sand blast method does not require any etchant for chemical reaction or any etch gas. According to the sand blast method, sands SD are applied to the preliminary dielectric layer L0 at a high pressure to collide with the preliminary dielectric layer L0, and thus the preliminary dielectric layer L0 is physically etched through the collision.

Subsequently, the mask pattern MP is removed. As a result, the first dielectric layer L1 is formed, and the protrusions 71 are formed on the first dielectric layer L1 at positions defined by the mask pattern MP.

In one or more embodiments, the preliminary dielectric layer L0 may be patterned using a photolithography method (alternative to or in addition to the sand blast method) to form the first dielectric layer L1 and the protrusions 71.

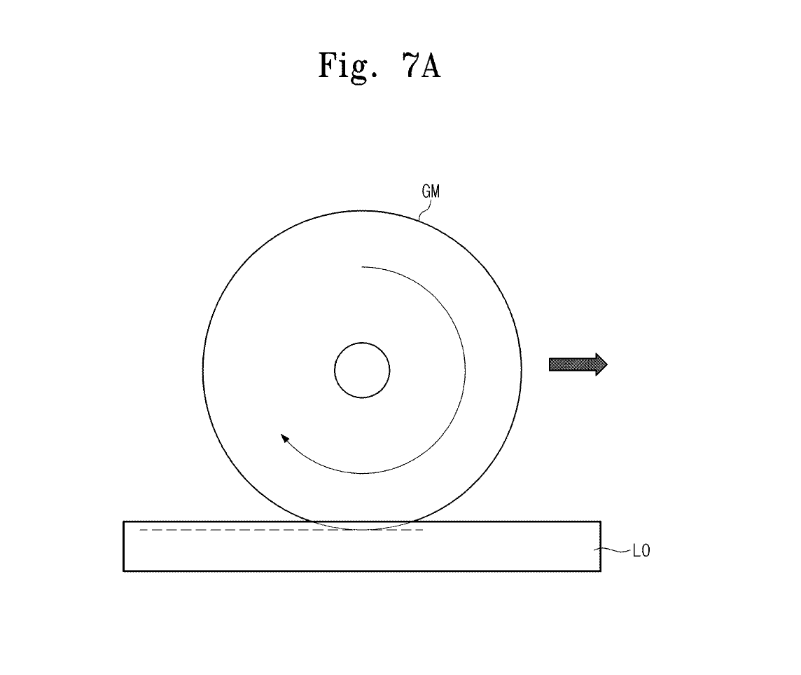

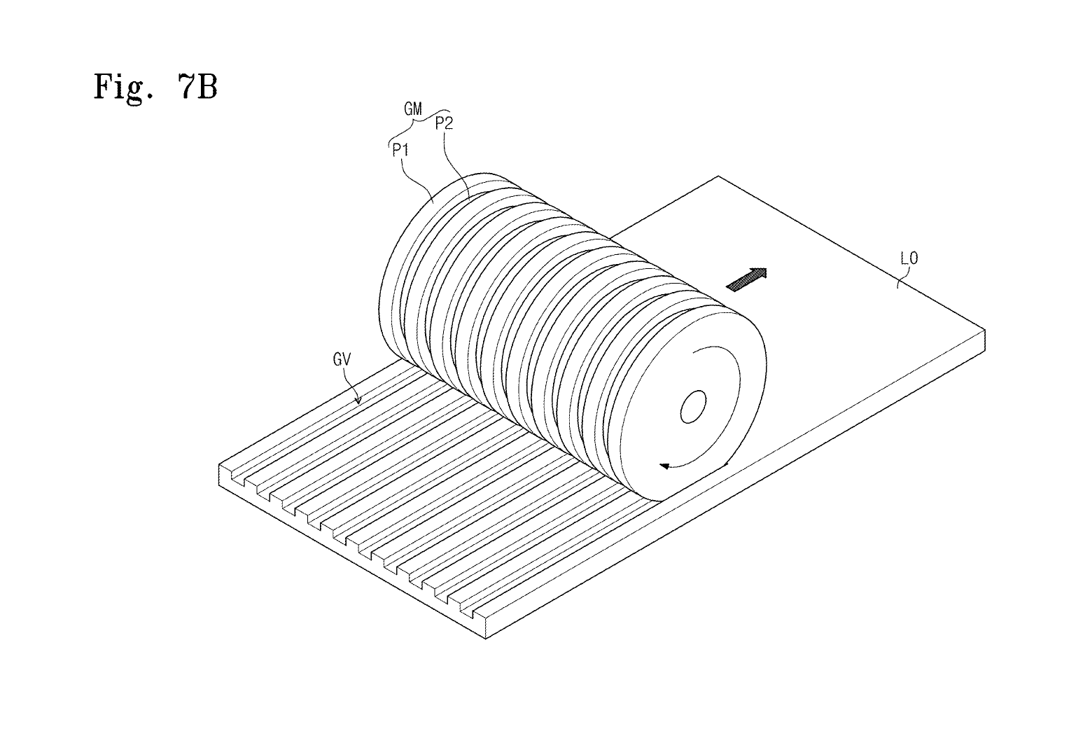

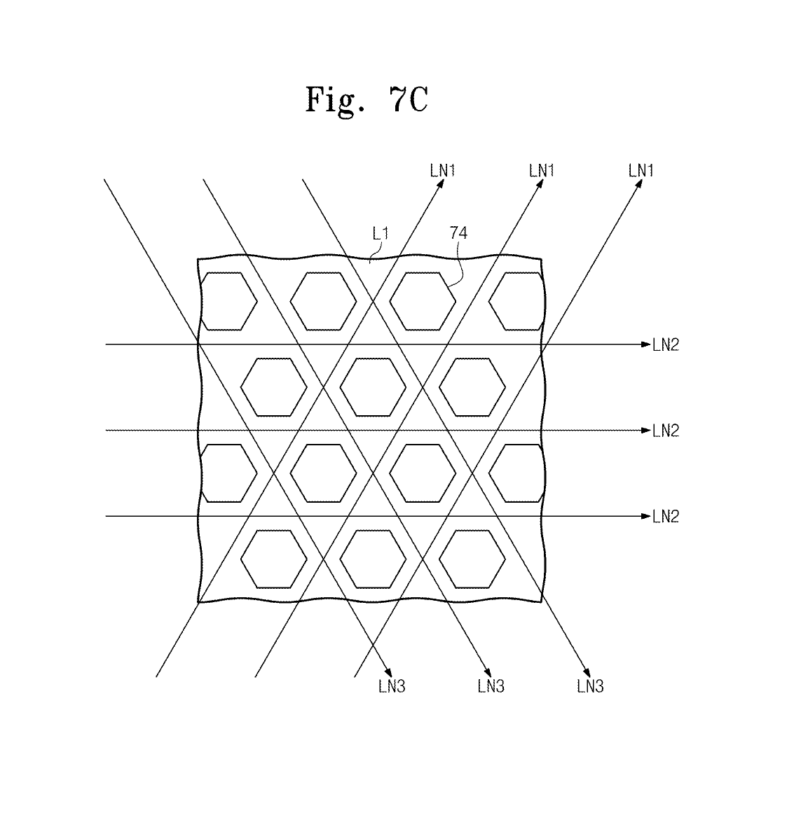

FIGS. 7A to 7C are views illustrating a method of manufacturing the first dielectric layer and the protrusions illustrated in FIG. 4B according to one or more embodiments of the present invention.

Referring to FIGS. 7A to 7C, a grinding member GM, e.g., a whetstone, is prepared. The grinding member GM has a roller shape and is configured to be rotate on the preliminary dielectric layer L0. In one or more embodiments, the grinding member GM includes a plurality of protruding portions P1, and the protruding portions P1 are spaced from each other, so that a groove P2 is formed between every two immediately adjacent protruding portions of the protruding portions P1.

The grinding member GM is operated to rotate on the preliminary dielectric layer L0, thereby grinding the preliminary dielectric layer L0 to form groove patterns GV in the preliminary dielectric layer L0. In one or more embodiments, the grinding member GM is disposed to allow the protruding portions P1 to correspond to (and align with) first lines LN1 in a one-to-one correspondence, and then a first grinding process is performed on the preliminary dielectric layer L0 using the grinding member GM. Subsequently, the grinding member GM is disposed to allow the protruding portions P1 to correspond to (and align with) second lines LN2 in a one-to-one correspondence, and then a second grinding process is performed on the preliminary dielectric layer L0 using the grinding member GM. Subsequently, the grinding member GM is disposed to allow the protruding portions P1 to correspond to (and align with) third lines LN3 in a one-to-one correspondence, and then a third grinding process is performed on the preliminary dielectric layer L0 using the grinding member GM.

After the first grinding process, the second grinding process, and the third grinding process have been performed on the preliminary dielectric layer L0, the groove patterns GV each of which having a width approximating the width of each of the protruding portions P1 are formed along the lines LN1, LN2, and LN3, and portions of the preliminary dielectric layer L0 that are not grinded by the grinding member GM remain. Thus, the first dielectric layer L1 and the protrusions 74, which have hexagonal top surfaces and are disposed on the first dielectric layer L1, are formed.

Although embodiments of the present invention have been described, it is understood that the present invention should not be limited to these embodiments. Various changes and modifications can be made by one ordinary skilled in the art within the spirit and scope of the present invention as hereinafter claimed.

What is claimed is:

1. An apparatus of treating a substrate, comprising:
a process chamber that provides a reaction space in which the substrate is treated; and
a substrate supporting unit disposed in the process chamber to support the substrate, the substrate supporting unit comprising:
a first dielectric layer disposed under the substrate; and
a plurality of protrusions that includes a dielectric material and is disposed on the first dielectric layer to make contact with the substrate, wherein the protrusions are spaced apart from each other and a distance between two protrusions adjacent to each other among the protrusions is in a range of about 0.01 to about two times of a thickness of the substrate.

2. The substrate treating apparatus of claim 1, further comprising a chuck to fix the substrate while interposing the first dielectric layer therebetween, wherein a ratio of an area in which the protrusions make contact with the substrate to an area in which the first dielectric layer makes contact with the chuck is in a range of about 0.1% to about 80%.

3. The substrate treating apparatus of claim 2, wherein the substrate supporting unit further comprises:
a first electrode disposed in the process chamber to face the first dielectric layer while interposing the chuck therebetween;
a second dielectric layer disposed between the chuck and the first electrode;
a cooling member to cool the first electrode; and
a second electrode disposed in the process chamber to form an electric field in the reaction space in cooperation with the first electrode.

4. The substrate treating apparatus of claim 3, further comprising a gas supply unit that supplies a process gas to the reaction space, wherein the process gas is converted into a plasma by the electric field.

5. The substrate treating apparatus of claim 4, wherein the dielectric material has a heat transmittance greater than a heat transmittance of the process gas.

6. The substrate treating apparatus of claim 5, wherein the substrate is an amorphous glass substrate, the process gas fills between the substrate and the first dielectric layer, and areas, in which a heat of the process gas is transmitted to an upper surface of the substrate from contact points, make contact with each other, wherein the lower surface of the substrate, the two protrusions adjacent to each other among the protrusions, and the process gas make contact with each other in the contact points.

7. The substrate treating apparatus of claim 6, wherein the areas are not spaced apart from each other.

8. The substrate treating apparatus of claim 5, wherein the dielectric material comprises aluminum oxide and the process gas comprises a helium gas.

9. The substrate treating apparatus of claim 1, wherein each of the protrusions has a polygonal shape when viewed in a plan view.

10. The substrate treating apparatus of claim 1, wherein each of the protrusions has a circular shape when viewed in a plan view.

11. The substrate treating apparatus of claim 1, wherein the protrusions are arranged in row and column directions and the protrusions of two adjacent rows are arranged in a zigzag form when viewed in a plan view.

12. The substrate treating apparatus of claim 1, wherein the protrusions are arranged along row and column directions in a matrix form.

13. The substrate treating apparatus of claim 12, further comprising a plurality of auxiliary protrusions disposed on the first dielectric layer and between two adjacent protrusions to each other among the protrusions, wherein a height of each of the auxiliary protrusions protruded from the first dielectric layer is smaller than a height of each of the protrusions protruded from the first dielectric layer.

14. A method for treating a substrate, the method comprising:
disposing the substrate inside a process chamber;
using a plurality of support elements to contact a bottom surface of the substrate for supporting the substrate, wherein the plurality of support elements includes a first support element and a second support element immediately neighboring the first support element, wherein a distance between the first support element and the second support element is less than or equal to two times a thickness of the substrate;
processing the substrate inside the process chamber; and
cooling the substrate using a cooling member, wherein a first heat is transferred from the substrate through the plurality of support members to the cooling member.

15. The method of claim 14, wherein the distance is greater than or equal to 0.01 mm.

16. The method of claim 14, further comprising using an electrostatic chuck to secure the substrate on the plurality of support elements,
wherein a total contact area of the bottom surface of the substrate contacted by the plurality of support elements has a first area size,
wherein an area of the dielectric layer contacted by the electrostatic chuck has a second area size, and
wherein a ratio of the first area size to the second area size is less than or equal to 80%.

17. The method of claim 16, wherein the ratio of the first area size to the second area size is greater than or equal to 0.1%.

18. The method of claim 18, wherein the ratio of the first area size to the second area size is less than or equal to 50%, and wherein the ratio of the first area size to the second area size is greater than or equal to 0.1%.

19. The method of claim 14,
wherein the first support element and the second support element are disposed on a dielectric layer,
wherein a protrusion is disposed on the dielectric layer and disposed between the first support element and the second support element,
wherein the protrusion is shorter than the first support element in a direction perpendicular to a bottom surface of the dielectric layer, and
wherein a second heat is transferred from the substrate through a gas to the protrusion.

20. The method of claim 19, wherein the second heat is transferred through the protrusion to the cooling element.
